(19) United States
(12) Patent Application Publication
(10) Pub. No.: US 2004/0114452 A1
(43) Pub. Date: Jun. 17, 2004

(54) Structure memory transfer device

(75) Inventors: Wen-Tsung Liu, Hsin-Dian City (TW); Chia-Li Chen, Hsin-Dian City (TW); Mi-Chang Chen, Hsin-Dian City (TW)

Correspondence Address: TROXELL LAW OFFICE PLLC, SUITE 1404, 5205 LEESBURG PIKE, FALLS CHURCH, VA, 22041, US

(73) Assignee: Wen-Tsung LIU

(21) Appl. No.: 10/366,472

(22) Filed: Feb. 14, 2003

(30) Foreign Application Priority Data
Dec. 17, 2002 (TW) 091220506

(51) Int. Cl. G11C 8/02

(52) U.S. Cl. 365/232

(57) ABSTRACT

An improved memory transfer device includes an outer body and a transfer module disposed in the outer body. The outer body defines a insert groove on one side and encases a transfer module, one side of the insert groove corresponding to a transfer model groove insert end. The insert end extends and defines plural groove positions for accepting at least one memory card. The character of the present invention is that one of the plural groove positions accepts and uses an xD memory card.

### THE FILED OF THE PRESENT INVENTION

The invention relates to an improved structure memory transfer device, especially relates to a memory transfer device using xD memory card and other various small memory cards.

### SUMMARY THE TRADITIONAL TECHNIQUE

Because the technique develop continuously, save media developed using the flash memory body has gradually become the mainstream of the market, usually be called electronic memory card, flash memory card, silicon CD card and so on. Said electronic memory card excel those save medias including the traditional diskette cards or CD cards one the function and character such as the convenience of taking, electricity-saving, information-keeping, velocity of information-transfer, repeating writing and reading, and anti-quake and anti-damp.

Just because the electric memory card has the predominant using characters and future, so many international electric manufactures such as Sony, TOSHIBA, SIEMENS, Panasonic, Samsung and SanDisk develop and launch in succession various types electric memory cards, such as PC card (PCMCIA ATA Flash Card), CF card (CompactFlash Card), SM (Smart Media Card), MMC card (MultiMedia Card), MS card (Memory Stick Card), SD card (Secure Digital Card) used in the digital products that those manufactures mainly launched such as digital camera, digital video camera, digital walkman, PDA to save software information such as image, music and cartoon.

Because electric memory card provides direct information circulation only to digital products, the circulation of information between various computer mainframes (such as table-type PC, notebook PC, industry computer, video decoder and so on) need be carried by various memory information reading device (another name is card-reader, silicon CD or transfer card).

The said memory reading device can be classed into two types: one reading device that can only use single memory card and is inconvenience in use, another reading device that can use various memory cards to make itself has better character in use. But, both the reading devices of single and various type can only use the memory cards that made in ISO regulation and has been disclosed, and have the shortcoming that cannot use xD memory card that has been launched on market and so result in inconvenience to user.

Although what above-mentioned disclose the background and shortcoming of memory card reading device, but there are many invent studies in the said reference information not has not be considered, for instance:

1.The information-reading device be designed usually into reading device that only use single type memory card.

2.If the information=reading device be designed into reading device that can use plural types memory card, and most of them be designed into reading device having plural insert grooves, the design not only insults in the volume of reading device is huge, in convenient-taking and also increase the cost of buying.

3.If the information-reading device is reading device of various type, can it be design into a small memory card that can use launched recently xD or other cards that launched later?

4.Can the reading device be designed into a reading device that can use all the disclosed and disclosed recently memory cards and has a minimal volume and the character of easy-taking, easy-used.

5.Can the transfer interface of the reading memory be designed into two types or more than two types and can provide user with more selects of using character.

Whereas the above-mentioned memory information-reading device has the above-said reconstruct room, so the inventor of the present invention improved those shortcomings and invent the present invention.

### OBJECT OF THE INVENTION

The main object of the present is to provides a improved construct memory transfer device that can encase plural and different types memory card groove positions to can further use xD memory card or other launched recently small memory cards to have many choices and convenience in using.

To realize the object, the present invention provides an improved construct memory transfer device, which at least comprises a outer body and a transfer module disposed in the said outer body; wherein the one side of outer body has insert groove and the interior of outer body has transfer module, the appropriate side of said outer body has at least one transfer interface to make memory card information circulate between accept set or sent set and memory card. One side of said transfer module corresponding to insert groove has insert end, said insert end extend entad define plural groove positions for accepting at least one memory cards, one of said plural groove positions encase and use xD memory card.

The other object of the present invention, the appropriate position of outer of the present invention has at least one transfer interface (such as USB, IEEE1394, PAMICA, Serial ATA, IDE, CF) to provides user with many choices in using transfer interface to reduce the inconvenience in using resulted from the traditional memory transfer device designed only for single transfer interface.

The detail construct, appliance principal, actions and effects will be described hereinafter, with reference to the description according to the drawings.

### THE PREFERRED EMBODIMENT OF THE PRESENT INVENTION

Please refers to FIG. 1, the present invention mainly comprises: a outer body 1 and a transfer module 2 disposed in outer body 1,wherein the appropriate position of one end of outer body 1 has a transfer interface 14, the other end has an insert groove 13; said transfer module 2 is disposed within outer body 1 and define an insert end 21 correspond to the insert groove 13 of outer body 1, and extend entad from insert groove 21 use the overlap room define at least two types, standards memory card insert groove positions 22A, 22B, 22C, 22D. The main character of the present invention is: one groove position 22D of the groove positions is designed into a insert groove that can encase and use three xD cards.

The preferred embodiment of the present invention, please refers to FIG. 2, the grooves 22A, 22B, 22C, 22D are designed into that can be used by at least two types memory cards (may be SM, SD, MMC, RS MMC, MS, MS Duo memory card arranged stagger) not in the same time: and the outer body 1 of the present invention can has at least one type transfer interface 14, wherein, the transfer interface 14 may be USB, IEEE1394, PCMCIA, IEEE1394, PCMCIA, Serial ATA, IDE or FC to provides user with the convenience in using the transfer interface 14 and has the convenience of many choices to decrease the inconvenience in the using resulted from the traditional memory transfer device that only use the single transfer interface.

The above-mentioned groove position 22A is for SM card inserting into, groove position 22B is for MS or MS Duo inserting into, groove position 22C is for SD and/or MMS and/or RS MMC cards inserting into.

According to adoptive the embodiment of present invention, the memory transfer device at least comprises outer body 1 and transfer module 2 disposed within outer body 1, wherein outer body 1 may be a outer engaged or inner engaged outer body composes of up body 11, lower body 12 that define a unit or separate respectively, and one end of outer body 1 define a insert groove 13A, and vicinity of insert groove 13 have one or more than one transfer interface(s) 14, one end or appropriate position of outer body 1 has at least one transfer interfaces, can provides user with convenience of multi-transfer.

And, outer body 1 has at least one insert groove 13B in the appropriate position near insert groove 13A for various type PC card or CF card inserting into. Transfer module 2 is disposed within outer body 1, and extend entad form insert end 21 use the overlap room define at least two or more than two types and standards memory card insert groove positions 22A, 22B, 22C, 22D. The main character of the present invention is: one groove position 22D of said groove positions may encase and use three xD cards to provide user with effect of using three xD card.

The transfer module 2 of present invention may has control board 23, the control board 23 is electrical connected with transfer interface 14 to make signal of memory card inserted in transfer module 23 circulate through control board 23 between mainframe or accept set and memory card.

Another embodiment of the present invention, as shown in FIG. 4, the outer body 1 at least comprises frame 15 and cover board 16, one end of outer body 1 defines insert groove 13, the other end defines PCMCIA and/or CF transfer interface 17, the interior of the outer body 1 has a transfer module having control board 23; one end of said transfer module 2 corresponding to insert groove 13 define insert groove 21 and use overlap room extend horizontally to another end from insert end 21 defines plural groove positions 22A, 22B, 22C, 22D for at least one type memory cards such as SM, SD, MMC, RS MMC, MS, MS Duo inserting into. The main character of the present invention is: one groove position 22D of plural groove positions is used for encasing and using three xD card to entitle user to use xD card.

The present invention may has at least one transfer interface 14 (for example USB, IEEE1394) in the appropriate position adjacent insert groove 13 to provide user with many choices in using transfer interface, so has the character of many purposes, to reduce the inconvenience in using resulted from traditional memory transfer device designed only for single transfer interface.

We can concluded from the above-mentioned, the memory transfer device of present invention can realize the expected effect and design, and the present invention has not be used in publicity and comply with the regulation of applying an invention, so we make a application.

Be noticed, while the present invention has been described above with reference to a preferred embodiment, and various modifications may be made without departing from the scope of the invention as defined by the appended claims.

### BRIEF DESCRIPTION OF THE DRAWINGS

FIG. 1 is a perspective sketch view of the memory transfer device of the present invention;

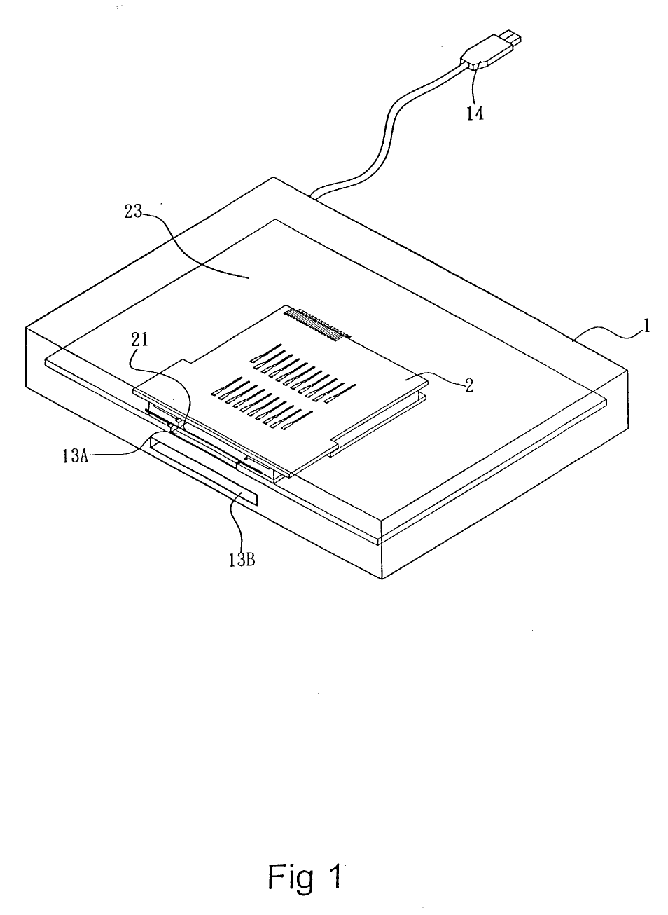

FIG. 2 is an exploded perspective view of the present invention;

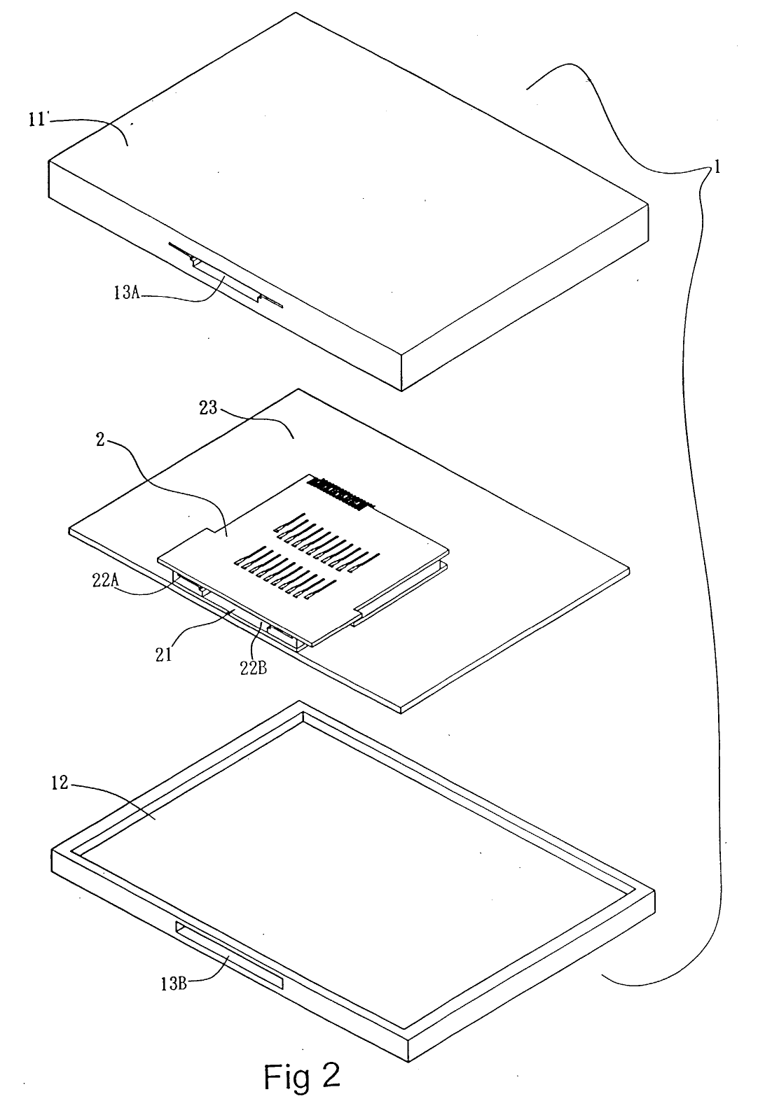

FIG. 3 is a exploded perspective view of the transfer module of present invention;

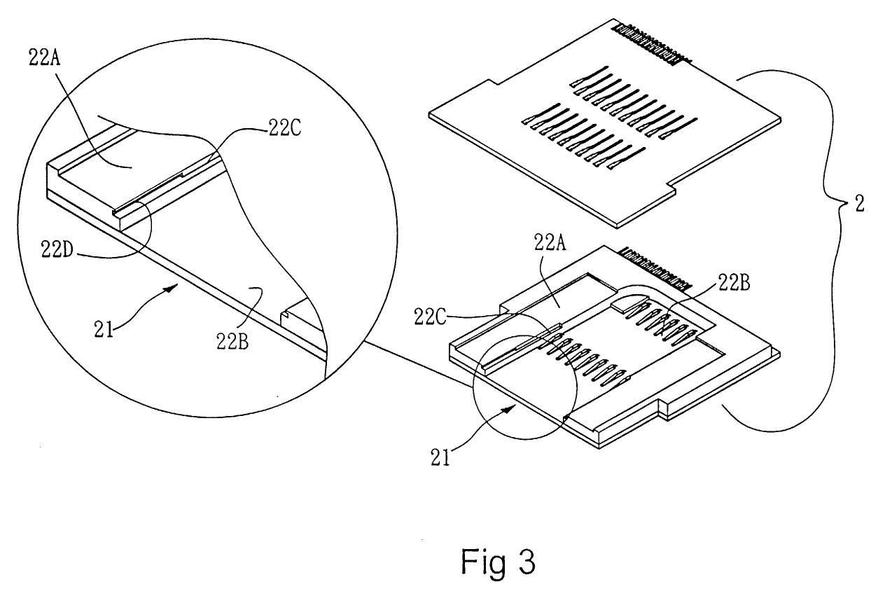

FIG. 4 is a perspective view of the present invention;

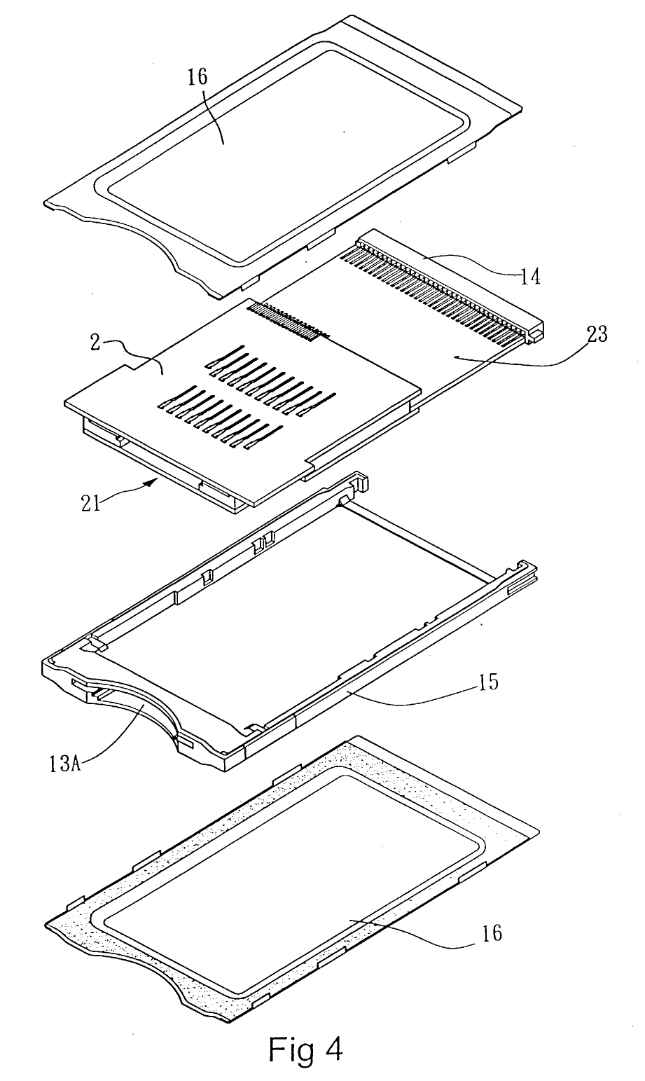

FIG. 5 is a sketch view of the embodiment of the present invention.

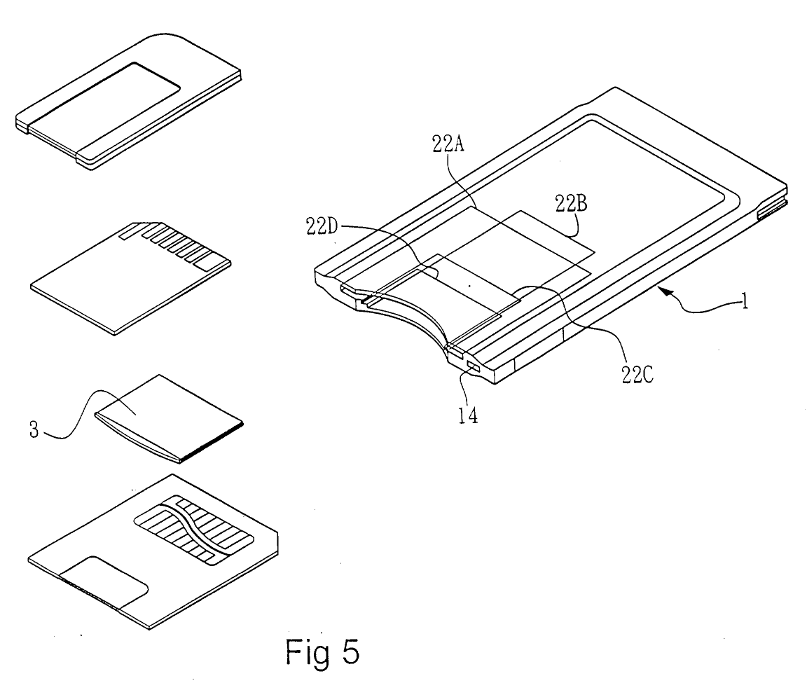

### THE DESCRIPTION OF SYMBOLS OF THE DRAWINGS

1 outer body

2.transfer module

11.top cover

21. insert end

12.lower cover

22A. insert groove

13A, 13B. insert groove

22B. insert groove

14. transfer interface

22C. insert groove

15. frame

22D. insert groove

16. cover board

23. control board

What is claimed is:

1. A improved structure memory transfer device at least comprising: one outer body and a transfer module disposed within said outer body; one side of outer body defines insert groove and has transfer module, the side of transfer module corresponding said insert groove defines insert end, said insert groove entad defines plural groove positions encasing at least one memory card, wherein one groove position of plural groove position is designed for encasing and using xD memory card.

2. The improved structure memory transfer device according to claim 1, wherein outer body is inner or outer engaged outer body consists of top, lower body with the structure of one unit or separate mode, one end of outer body defines an insert groove and has one or more than one transfer interface near said insert groove, and the appropriate position of outer body has at least one transfer interface to provides user with multi-transfer in using.

3. The improved memory structure transfer device according to claim 1, wherein transfer module extends entad horizontally use overlap room to define plural insert grooves for at least two types, standards memory cards (be SM, SD, MMC, RS MMC, MS, MS Duo such as memory card arranged stagger) inserting into.

4. The improved structure memory transfer device according to claim 1, wherein the appropriate position near insert groove of outer body has at least one insert groove for various types PC or CF card or other memory card inserting into.

5. The improved memory transfer device according to claim 1, wherein transfer module has control board, said control board electrically connected with transfer interface to make signal of memory card that inserted into transfer module circulate by control board between mainframe or accept set and memory card.

6. The improved structure memory transfer device according to claim 1, wherein transfer interface is one of or more than one of USB,IEEE1394, PCMCIA, Serial ATA, IDE or CF.

7. The improved memory transfer device according to claim 1, wherein outer body at least comprises a frame body and cover board, and one end of outer body defines insert groove, the other end is PCMCIA or CF transfer interface, and interior of said outer body has a transfer mode group having a control board, being a transfer device of PC card or ADAPTER card by said construct.
